(19) United States
(12) Patent Application Publication
(10) Pub. No.: US 2008/0128857 A1
(43) Pub. Date: Jun. 5, 2008

(54) Multi-Finger Capacitor

(75) Inventor: Han Bi, Shanghai (CN)

Correspondence Address: BEVER, HOFFMAN & HARMS, LLP, 1432 CONCANNON BLVD, BUILDING G, LIVERMORE, CA, 94550-6006, US

(73) Assignee: INTEGRATED DEVICE TECHNOLOGY, INC., San Jose, CA (US)

(21) Appl. No.: 11/949,002

(22) Filed: Nov. 30, 2007

Related U.S. Application Data
(60) Provisional application No. 60/868,668, filed on Dec. 5, 2006.

(51) Int. Cl. H01L 29/86

(52) U.S. Cl. 257/532; 257/E29.325

(57) ABSTRACT

A multi-finger capacitor structure includes a capacitor input node having a first set of conductive fingers, a capacitor output node having a second set of conductive fingers interleaved with the first set of conductive fingers, and a conductive plate and/or pattern connected to the capacitor input node, and located between a substrate and the first and second sets of interleaved conductive fingers. The conductive plate/pattern renders the parasitic capacitance of the capacitor output node negligible, thereby imparting desirable operating characteristics to the capacitor structure. The capacitor input node may also include Faraday electric walls that laterally surround the capacitor output node, thereby limiting electrical energy leakage.

### RELATED APPLICATION

The present application is related to, and claims priority of, U.S. Provisional Patent Application Ser. No. 60/868,668 filed by Han Bi on Dec. 5, 2006.

### FIELD OF THE INVENTION

The present invention relates to multi-finger capacitors. More specifically, the present invention relates to multi-finger capacitors used for alternating current (AC) signal coupling.

### RELATED ART

Analog integrated circuits, such as SERDES I/O circuits, often require high quality capacitors for AC signal coupling. For example, a high-quality capacitor may be used to implement capacitive AC coupling in the last stage of a multi-stage current mode logic clock buffer, in order to remove the accumulated duty cycle error.

FIG. 1 is an isometric diagram of a conventional multi-finger capacitor 100 used for the above-described purpose. Capacitor 100 is formed by multiple metal layers 101-103, which are joined by multiple via layers 104-105 of a semiconductor process. The first metal layer 101 includes metal traces 111-112, the second metal layer 102 includes metal traces 113-114, and the third metal layer 103 includes metal traces 115-116.

FIG. 2A is a top view of metal traces 111 and 112 of the first metal layer 101. Metal trace 111 includes metal fingers 201-204, which are joined by a metal base region 205. Metal trace 112 similarly includes metal fingers 211-214, which are joined by a metal base region 215. Metal traces 111 and 112 are electrically insulated from one another by dielectric material (not shown), with the metal fingers 201-204 of metal trace 111 interleaved with (and adjacent to) the metal fingers 211-214 of metal trace 112.

FIG. 2B is a top view of metal traces 113 and 114 of the second metal layer 102. Metal trace 113 includes metal fingers 221-224, which are joined by a metal base region 225. Metal trace 114 similarly includes metal fingers 231-234, which are joined by a metal base region 235. Metal traces 113 and 114 are electrically insulated from one another by dielectric material (not shown), with the metal fingers 221-224 of metal trace 113 interleaved with (and adjacent to) the metal fingers 231-234 of metal trace 114. Note that the orientation of the metal fingers alternates in consecutive metal layers 101 and 102. As a result, metal fingers 231-235 overlie (overlap) metal fingers 201-204, respectively, and metal fingers 221-224 overlie metal fingers 211-214, respectively.

The metal traces 115 and 116 of the third metal layer 103 have the same layout as the metal traces 111 and 112 of the first metal layer 101. Metal trace 115 includes metal fingers 241-244, which are joined by a metal base region 245. Metal trace 116 similarly includes metal fingers 251-254, which are joined by a metal base region 255. Metal traces 115 and 116 are electrically insulated from one another by dielectric material (not shown), with the metal fingers 241-244 of metal trace 115 interleaved with (and adjacent to) the metal fingers 251-254 of metal trace 116.

The structure of multi-finger capacitor 100 can be extended vertically by adding additional metal and via layers over the third metal layer 103, with all ‘odd’ metal layers having the same layout as the first metal layer 101, and all ‘even’ metal layers having the same layout as the second metal layer 102.

Via layer 104 includes one set of conductive via plugs that electrically connect the metal base regions 205 and 215 of metal traces 111 and 113, and another set of conductive via plugs that electrically connect the metal base regions 225 and 235 of metal traces 112 and 114. Similarly, via layer 105 includes one set of conductive via plugs that electrically connect metal traces 113 and 115, and another set of conductive via plugs that electrically connect metal traces 114 and 116.

Commonly connected metal traces 111, 113 and 115 form an input node 120 of the multi-finger capacitor 100 (which is shaded in FIGS. 1-3), and commonly connected metal traces 112, 114 and 116 form an output node 121 of capacitor 100 (which is un-shaded in FIGS. 1-3). The input and output capacitor nodes 120-121 are separated by dielectric material (not shown) of the semiconductor process.

FIG. 3 is a cross sectional view of the metal fingers of metal traces 111-116, along a plane perpendicular to the metal layers 101-103. FIG. 3 illustrates the substrate 301, over which the metal layers 101-103 are fabricated. The metal traces of the capacitor input node 120 are shaded, and the metal traces of the output node 121 are un-shaded in FIG. 3.

In general, adjacent metal fingers in the same metal layer belong to opposite signal nodes. For example, in the first metal layer 101, metal fingers 201-204 belong to the capacitor input node 120, and metal fingers 211-214 belong to the capacitor input node 121. The capacitance between adjacent metal fingers in the same metal layer is hereinafter referred to as a sidewall capacitance. FIG. 3 illustrates an exemplary sidewall capacitance C_{S} between fingers of metal traces 111 and 112. Between adjacent metal layers, overlapping metal fingers belong to opposite signal nodes. For example, in the first metal layer 101, metal fingers 201-204 belong to the capacitor output node 121, while the overlapping metal fingers 231-234 belong to the capacitor input node 120. The capacitance between overlapping metal fingers in adjacent metal layers is hereinafter referred to as an overlap capacitance. FIG. 3 illustrates an exemplary overlap capacitance C₀ between the fingers of metal traces 111 and 114. Capacitor 100 therefore includes both sidewall capacitance between adjacent fingers and overlap capacitance between overlapping fingers. The effective coupling capacitance C_{C} of capacitor 100 is defined by the combined sidewall and overlap capacitances.

The standard design of multi-finger capacitor 100 is typically not modified, due to the fact that modifications will typically significantly increase the complexity of fabricating the capacitor structure, without significantly improving the performance of the capacitor structure.

The performance of metal finger capacitors, such as capacitor 100, is typically specified by two parameters: (1) capacitive loading seen from the input node of the capacitor, and (2) AC coupling loss of the capacitor. It is desirable for both of these parameters to be low.

As illustrated by the cross section of FIG. 3, capacitor 101 suffers from electrical field leakage out of the finger structure, which generates two parasitic capacitances C_{PI} and C_{PO}. The parasitic input capacitance C_{PI} exists between the capacitor input node 120 and the grounded substrate 301. The parasitic output capacitance C_{PO} exists between the capacitor output node 121 and the substrate 301. Each of these parasitic capacitances C_{PO} and C_{PI} has a value of about 5% of the effective coupling capacitance C_{C} in a generic 130 nanometer (nm) CMOS process.

FIG. 4 is a circuit diagram illustrating an equivalent electrical model of multi-finger capacitor 100 coupled to a load capacitance C_{L}. The capacitive loading seen from the input node 120 of the capacitor is equal to the sum of the parasitic capacitances C_{PI} and C_{PO}. The AC coupling loss (L_{C}) of capacitor 100 can be roughly represented by equation (1).

L_{C}=(C_{PO}+C_{L})/(C_{C}+C_{PO}+C_{L}) (1)

Accordingly, the greater the parasitic capacitance C_{PO}, the greater the AC coupling loss (L_{C}). It would therefore be desirable to have a multi-finger capacitor structure that significantly reduces the parasitic capacitance C_{PO} (thereby reducing the AC coupling loss L_{C}), without requiring a complex process to fabricate the capacitor.

### SUMMARY OF THE INVENTION

Accordingly, the present invention provides a multi-finger capacitor structure including a capacitor input node having a first set of conductive fingers, a capacitor output node having a second set of conductive fingers and interleaved with the first set of conductive fingers, and a conductive plate and/or pattern connected to the capacitor input node, and located between a substrate and the first and second sets of interleaved conductive fingers. The conductive plate/pattern renders the parasitic capacitance of the capacitor output node negligible, thereby resulting in a low AC coupling loss. The low AC coupling loss enables the multi-finger capacitor structure of the present invention to have a lower capacitance than a conventional multi-finger capacitor, for the same application. As a result, the multi-finger capacitor structure of the present invention can have a significantly smaller layout area, and have significantly lower driver power requirements, than a conventional multi-finger capacitor structure.

In accordance with another embodiment, the capacitor input node may also include Faraday electric walls that laterally surround the capacitor output node, thereby limiting electrical energy leakage.

The present invention will be more fully understood in view of the following description and drawings.

### BRIEF DESCRIPTION OF THE DRAWINGS

FIG. 1 is an isometric view of a conventional multi-finger capacitor structure.

FIGS. 2A and 2B are top views of odd and even metal layers, respectively, of the multi-finger capacitor structure of FIG. 1.

FIG. 3 is a cross sectional view of the metal fingers of the multi-finger capacitor structure of FIG. 1.

FIG. 4 is a circuit diagram of an electrical model of the multi-finger capacitor structure of FIG. 1 coupled to a load capacitance.

FIG. 5 is an isometric view of a multi-finger capacitor structure in accordance with one embodiment of the present invention.

FIGS. 6A and 6B are top view of odd and even metal layers, respectively, of the multi-finger capacitor structure of FIG. 5, in accordance with one embodiment of the present invention.

FIG. 7 is a cross sectional view of the metal fingers of the multi-finger capacitor structure of FIG. 5, in accordance with one embodiment of the present invention.

FIG. 8 is an isometric view of a multi-finger capacitor structure in accordance with an alternate embodiment of the present invention.

### DETAILED DESCRIPTION

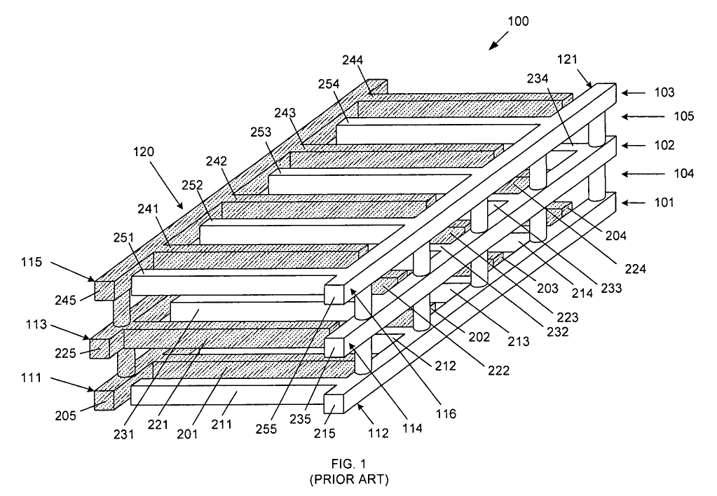

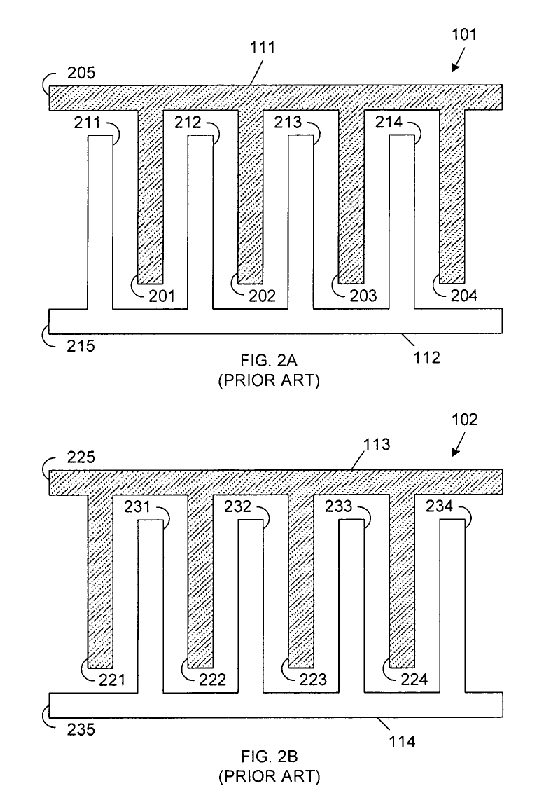

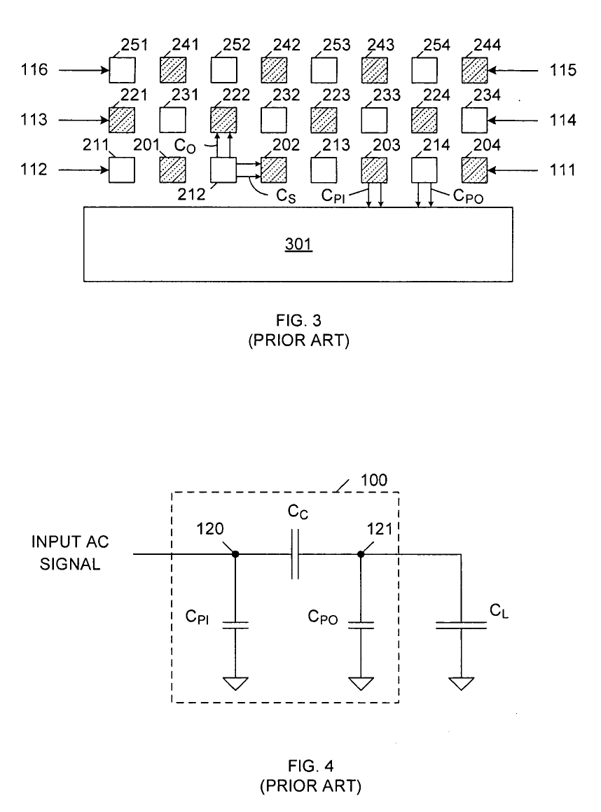

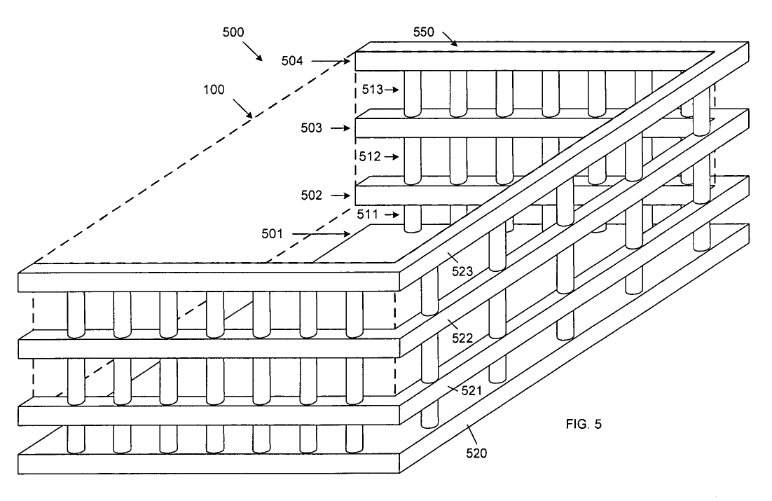

FIG. 5 is an isometric view of a multi-finger capacitor structure 500 in accordance with one embodiment of the present invention. Capacitor structure 500 includes the multi-finger capacitor 100 of FIG. 1 (which is illustrated as a dashed box in FIG. 5 for purposes of clarity), and a metal cage structure 550, which is electrically connected to the input node 120 of multi-finger capacitor 100. The manner in which the multi-finger capacitor 100 is coupled to the metal cage structure 550 is described in more detail below.

In the described embodiments, metal cage structure 550 includes four metal layers 501-504 and three via layers 511-513, which are formed over an underlying substrate (not shown in FIG. 5). In the embodiment illustrated by FIG. 5, the first metal layer 501 includes a metal plate 520, which is isolated from the underlying substrate by a dielectric material (not shown). The first via layer 511 provides one or more electrical connections between metal plate 520 and a first closed metal pattern 521 in the second metal layer 502. Note that only three sides of the first closed metal pattern 521 are explicitly illustrated in FIG. 5, as a fourth side of the first closed metal pattern 521 is provided by a portion of multi-finger capacitor 100.

The second via layer 512 provides one or more electrical connections between the first closed metal pattern 521 and a second closed metal pattern 522 in the third metal layer 503. Only three sides of the second closed metal pattern 522 are explicitly illustrated in FIG. 5, as a fourth side of the second closed metal pattern 522 is provided by a portion of multi-finger capacitor 100.

The third via layer 513 provides one or more electrical connections between the second closed metal pattern 522 and a third closed metal pattern 523 in the fourth metal layer 504. Only three sides of the third closed metal pattern 523 are explicitly illustrated in FIG. 5, as a fourth side is provided by a portion of multi-finger capacitor 100.

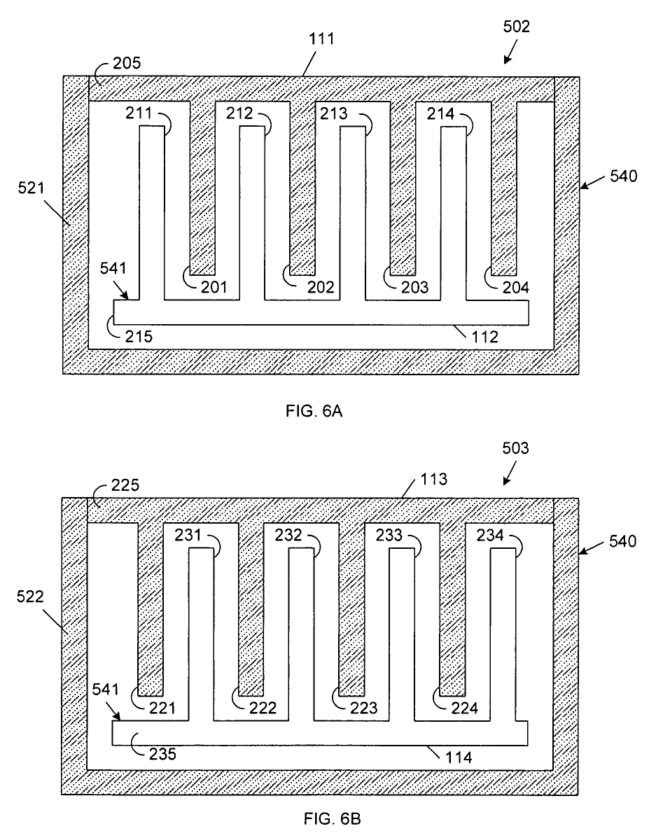

FIG. 6A is a top view of the second metal layer 502 of capacitor structure 500 in accordance with one embodiment of the present invention. As illustrated by FIG. 6A, the fourth side of the first closed metal pattern 521 is formed by the metal base region 205 of metal trace 111 of multi-finger capacitor 100. Note that the first via layer 511 may electrically connect the metal base region 215 to the underlying metal plate 520.

FIG. 6B is a top view of the third metal layer 503 of capacitor structure 500 in accordance with one embodiment of the present invention. As illustrated by FIG. 6B, the fourth side of the second closed metal pattern 522 is formed by the metal base region 225 of the metal trace 113 of capacitor structure 100.

The fourth metal layer 504 of capacitor structure 500 has the same pattern as the second metal layer 503. Thus, the fourth side of the third closed metal pattern 523 is formed by the base metal region 245 of the metal trace 115 of capacitor structure. An additional (fifth) metal layer 505 having the same pattern as the third metal layer 523 could be formed over the fourth metal layer 504, thereby extending the pattern. Thus, in other embodiments, capacitor 500 can be formed by other numbers of metal layers.

In accordance with the described embodiments, a capacitor input node 540 of capacitor 500 is formed by the commonly connected capacitor input node 120 of capacitor 100 and the metal cage structure 550. A capacitor output node 541 of capacitor 500 is formed by the capacitor output node 121 of capacitor 100.

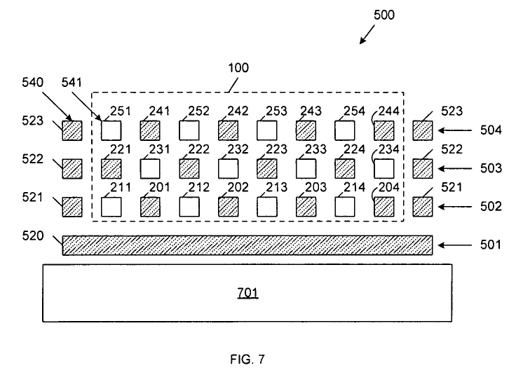

FIG. 7 is a cross sectional view of the metal fingers of capacitor structure 100, metal plate 520 and the closed metal patterns 521-523, along a plane perpendicular to the metal layers 501-504. FIG. 7 illustrates the substrate 701, over which the metal layers 501-504 are fabricated.

The metal traces of the capacitor output node 541 (which are un-shaded in FIG. 7) are shielded from the underlying substrate 701 by the metal traces of the capacitor input node 540 (which are shaded in FIG. 7). In particular, metal plate 520, which forms part of the capacitor input node 540, shields the metal traces of the capacitor output node 541 from the substrate 701. As a result, the parasitic output capacitance C_{PO} of capacitor 500 (i.e., the parasitic capacitance between the capacitor output node 541 and the grounded substrate 701) is negligible. That is, the parasitic output capacitance C_{PO} of capacitor 500 can be approximated as 0 fF. Metal plate 520 results in an increased parasitic input capacitance C_{PI} of capacitor 500, when compared with the parasitic input capacitance C_{PI} of capacitor 100 (FIG. 1). More specifically, capacitor 500 exhibits a parasitic input capacitance C_{PI} that is slightly less than about 10% of the total capacitance C_{C} of multi-finger capacitor 100.

Moreover, the closed metal patterns 521-523 and the via plugs connecting these closed metal patterns form Faraday electrical walls on each side of the capacitor structure 500, laterally surrounding the capacitor output node 541. These Faraday electrical walls do not increase the total parasitic capacitance of capacitor 500. However, these Faraday electrical walls can help to prevent inner electrical energy from leaking out of capacitor 500.

Electromagnetic field analysis of the multi-finger capacitor 500 shows that the reduction in the parasitic output capacitance C_{PO} increases the ratio of C_{C}/C_{PO} by more than 15 times. At the same time, the ratio of C_{C}/(C_{PI}+C_{PO}) is slightly reduced. Therefore, the overall electrical performance of capacitor 500 is significantly improved with respect to the overall electrical performance of capacitor 100.

Capacitor 500 may be used to effectively reduce the required layout area of a multi-finger capacitor, while also reducing the required power of an associated driver circuit, when compared with conventional capacitor 100. For example, suppose that a driver circuit is configured to drive an AC signal to the capacitor input node 120 of capacitor 100, and that a capacitive load (C_{L}) of 50 fF is coupled to the capacitor output node 121 of capacitor 100.

In order to achieve an AC coupling factor L_{C} less 10% in these conditions, the conventional multi-finger capacitor 100 must have a capacitance of about 833 fF. As described above, the conventional multi-finger capacitor 100 exhibits a parasitic input capacitance C_{PI} and a parasitic output capacitance C_{PO}, each equal to about 5% of the total capacitance C_{C}. In this case, the parasitic capacitances C_{PO} and C_{PI} are each equal to about 41.65 fF (i.e., 5% of 833 fF). Substituting the values of C_{L}, C_{C} and C_{PO} into equation (1) results in the following, which confirms the above analysis.

L_{C}=(41.65+50)/(833+41.65+50)=9.9% (2)

In this example, the parasitic capacitances C_{PO} and C_{PI} of the conventional multi-finger capacitor 100 combine to load the input node 120 with a capacitance of about 83.3 fF (i.e., C_{PO}+C_{PI}=83.3 fF).

Now suppose that the multi-finger capacitor 500 of the present invention is used to replace the conventional multi-finger capacitor 100 in the present example. That is, suppose that a driver circuit is configured to drive an AC signal to the capacitor input node 540 of capacitor 500, and that a capacitive load (C_{L}) of 50 fF is coupled to the capacitor output node 541 of capacitor 500. In order to achieve an AC coupling factor L_{C} less than 10%, the multi-finger capacitor 500 of the present invention must have a capacitance of about 454 fF. As described above, the multi-finger capacitor 500 of the present invention has a parasitic input capacitance C_{PI} equal to about 10% of the total capacitance C_{C}, and a negligible parasitic output capacitance C_{PO}. In this case, the parasitic input capacitance C_{PI} is equal to about 45.4 fF (i.e., 10% of 454 fF), and the parasitic output capacitance C_{PO} can be estimated as 0 fF. Substituting the values of C_{L}, C_{C} and C_{PO} into equation (1) results in the following, which confirms the above analysis.

L_{C}=(0+50)/(454+0+50)=9.9% (3)

### In this example, the parasitic capacitances C_{PO} and C_{PI} of multi-finger capacitor 500 load the input node 540 with a capacitance of about 45.4 fF (i.e., C_{PO}+C_{PI}=45.4 fF).

In the above-described example, the required capacitance of capacitor 500 (i.e., 454 fF) is significantly less than the required capacitance of a conventional capacitor 100 (i.e., 833 fF) to achieve the same AC coupling factor. This reduced required capacitance translates into a reduced required layout area of capacitor 500 (with respect to the required layout area of conventional capacitor 100). For example, the required layout area of capacitor 500 may be reduced by about 83% with respect to the required layout area of conventional capacitor 100.

Moreover, the capacitive loading introduced at the input node 540 of capacitor 500 (i.e., 45.4 fF) is significantly less than the capacitive loading introduced at the input node 120 of conventional capacitor 100 (i.e., 83.3 fF). The reduced capacitive input node loading along with the reduced required capacitance translates into a reduced required power of the driver circuit. For example, the power requirement of a driver circuit configured to drive capacitor 500 may about 39.7% less than the power requirement of a driver circuit configured to drive conventional capacitor 100.

Advantageously, multi-finger capacitor 500 of the present invention is a high-density, a high quality factor capacitor that can be fabricated using a generic digital process. The capacitance of multi-finger capacitor 500 will not vary with voltage.

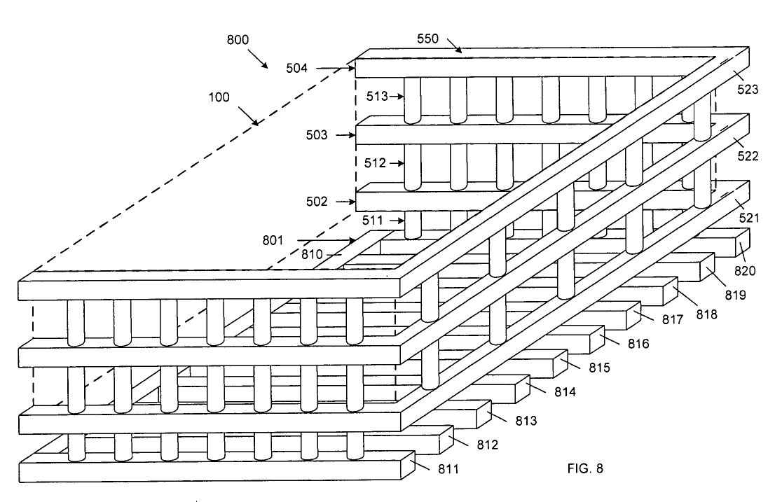

FIG. 8 is an isometric view of a multi-finger capacitor 800 in accordance with an alternate embodiment of the present invention. Because multi-finger capacitor 800 is similar to multi-finger capacitor 500, similar elements are labeled with similar reference numbers in FIGS. 5 and 8. The multi-finger capacitor 800 is substantially identical to multi-finger capacitor 500. However, the metal plate 520 of the first metal layer 501 of capacitor 500 is replaced with a plurality of commonly connected metal traces 810-820 in the first metal layer 801 of capacitor structure 800. The metal traces 810-820 are electrically connected to the capacitor input node by the first via layer 510. Metal traces 810-820 prevent electrical energy from leaking out of the capacitor 800 in the same manner that metal plate 520 prevents electrical energy from leaking out of capacitor 500. In an alternate embodiment, a metal trace identical to (and parallel to) metal trace 810 is used to connect the exposed ends of metal traces 811-820.

Although the invention has been described in connection with several embodiments, it is understood that this invention is not limited to the embodiments disclosed, but is capable of various modifications, which would be apparent to one of ordinary skill in the art. For example, although the capacitors described herein have eight metal fingers per metal layer, it is understood that these capacitors can have other numbers of metal fingers per metal layer. Moreover, although the capacitors described herein have conductive fingers made of metal, it is understood that other conductive materials may be used to form these fingers in alternate embodiments. Thus, the present invention is only intended to be limited by the following claims.

I claim:

1. A multi-finger capacitor structure comprising:
a capacitor input node located over a substrate, and comprising a first set of one or more conductive traces located in a first conductive layer, and a second set of conductive traces located in a first set of one or more conductive layers over the first conductive layer; and
a capacitor output node located entirely over the first conductive layer, and comprising a third set of conductive traces located in the first set of one or more conductive layers.

2. The multi-finger capacitor structure of claim 1, wherein the first set of one or more conductive layers comprises a second conductive layer located over the first conductive layer, wherein the second conductive layer comprises a first set of conductive fingers of the capacitor input node interleaved with a first set of conductive fingers of the capacitor output node.

3. The multi-finger capacitor structure of claim 2, wherein the first set of one or more conductive layers comprises a third conductive layer located over the second conductive layer, wherein the third conductive layer comprises a second set of conductive fingers of the capacitor input node interleaved with a second set of conductive fingers of the capacitor output node.

4. The multi-finger capacitor structure of claim 3, wherein the second set of conductive fingers of the capacitor input node are aligned over the first set of conductive fingers of the capacitor output node, and wherein the second set of conductive fingers of the capacitor output node are aligned over the first set of conductive fingers of the capacitor input node.

5. The multi-finger capacitor structure of claim 2, wherein the second conductive layer further comprises a first closed conductive pattern connected to and laterally surrounding the first set of conductive fingers of the capacitor input node.

6. The multi-finger capacitor structure of claim 5, wherein the first closed conductive pattern laterally surrounds the first set of conductive fingers of the capacitor output node.

7. The multi-finger capacitor structure of claim 1, wherein the first set of one or more conductive traces of the first conductive layer comprises a conductive plate having edges that define a perimeter of the capacitor structure.

8. The multi-finger capacitor structure of claim 1, wherein the first set of one or more conductive traces of the first conductive layer comprise a plurality of conductive traces aligned with the overlying second and third sets of conductive traces.

9. The multi-finger capacitor structure of claim 8, wherein the plurality of conductive traces of the first conductive layer are electrically connected to one another.

10. A semiconductor structure comprising:
a substrate;
a multi-finger capacitor located over the substrate, and comprising a capacitor input node having a first plurality of fingers and a capacitor output node having a second plurality of fingers interleaved with the first plurality of fingers; and
a first set of one or more conductive traces located between the multi-finger capacitor and the substrate, and connected to the capacitor input node.

11. The semiconductor structure of claim 10, further comprising a load capacitor (C_{L}) coupled to the capacitor output node.

12. The semiconductor structure of claim 10, wherein the first set of one or more conductive traces are aligned with the first plurality of fingers and the second plurality of fingers.

13. The semiconductor structure of claim 10, further comprising a plurality of Faraday electric walls located around the capacitor output node.

14. The semiconductor structure of claim 13, further comprising one or more electrical connections between the Faraday electric walls and the capacitor input node.

15. The semiconductor structure of claim 13, further comprising one or more electrical connections between the Faraday electric walls and the first set of one or more conductive traces.
